(19) United States
(12) Patent Application Publication
(10) Pub. No.: US 2003/0061989 A1
(43) Pub. Date: Apr. 3, 2003

(54) Semiconductor manufacturing system

(75) Inventors: Masaki Kamimura, Yokohama-shi (JP); Takashi Nakao, Kawasaki-shi (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA

(21) Appl. No.: 10/231,073

(22) Filed: Aug. 30, 2002

(30) Foreign Application Priority Data
Aug. 31, 2001 (JP) 2001-265013

(51) Int. Cl. B05C 11/00; C23C 16/00

(52) U.S. Cl. 118/712; 118/724

(57) ABSTRACT

A semiconductor device manufacturing system is disclosed, which comprises a film forming device including a film forming chamber and a heater, the film forming chamber configured to accommodate a substrate and form a film on the substrate, the heater configured to heat the substrate, a temperature controller including a temperature detector and a heater controller, the temperature detector configured to detect a temperature of at least one of inside and outside the film forming chamber, the heater controller configured to control the heater to heat the substrate at a predetermined temperature according to the temperature detected by the temperature detector, and a system controller including a film formation end time determining device configured to determine an end time of the film formation, before the temperature detected by the temperature detector is substantially constant and after the substrate is heated by the heater.

### CROSS-REFERENCE TO RELATED APPLICATIONS

This application is based upon and claims the benefit of priority from the prior Japanese Patent Application No. 2001-265013, filed Aug. 31, 2001, the entire contents of which are incorporated herein by reference.

### BACKGROUND OF THE INVENTION

1. Field of the Invention

The present invention relates to a semiconductor manufacturing system including a film forming device.

2. Description of the Related Art

As a film forming device, a low pressure (LP) chemical vapor deposition (CVD) apparatus has been well known. As a method for forming a film having a desired film thickness using the LP-CVD apparatus, such a method in which a film formation rate is beforehand investigated, a film formation time is computed from that film formation rate and a source gas is introduced for that film formation time has been known.

Because logarithm of the film formation rate is proportional to the inverse number of a temperature under an ideal reaction, the film formation time can be automatically acquired by computation. However, because such ideal reaction is impossible to achieve actually, ordinarily, determination and computation of the film formation end time are carried out by human power.

In order to minimize the fluctuation of the film formation time to make the determination and computation of the film formation end time appropriate and easy, the formation of film is executed under a constant film formation rate or under a stable wafer temperature. Thus, the wafer needs to be heated up to a predetermined temperature before the film formation is started, so that it is necessary to wait for about 20-40 minutes until the temperature is stabilized. That is, there is such a problem that the film forming process takes a considerable process time.

Usually, the temperature of a wafer is measured with a thermocouple provided in a quartz tube. The thermocouple is used also for temperature control within a chamber. By feeding back the voltage measured with the thermocouple to a heater, the temperature within the chamber is controlled.

However, because the quantity of wafers set in the chamber, wafer placement position and the volume of substance generated within the chamber by feeding gas into the chamber change depending on each the film forming process, the optical characteristic of the quartz tube is changed. As a result, the quantity of heat produced by mainly radiation, which the thermocouple acquires, is changed, so that the temperature of a wafer measured with the thermocouple (apparent wafer temperature) is different from a wafer temperature (real temperature).

In an ordinary LP-CVD apparatus, time taken from start of film forming process to start of film forming changes depending on residual substance in the chamber due to previous film forming process, pump performance and atmospheric pressure. This is why the time taken from start of film forming process to start of film forming varies depending on each film forming process. However, there has not been proposed any appropriate method for comparing a progress of temperature change in film forming process which takes into account that deviation of time among various film forming processes. For the reason, it has been impossible to recognize a difference in the film forming process environment mainly with respect to changes in temperature.

As described above, according to the conventional film forming method using the LP-CVD apparatus, a time for waiting for temperature to be stabilized before starting the film forming is indispensable because the temperature of a wafer must be stabilized at the time of film forming. Consequently, there is such a problem that the film forming process time necessary for the film forming takes long.

### BRIEF SUMMARY OF THE INVENTION

According to aspect of the present invention, there is provided a semiconductor device manufacturing system comprising: a film forming device including a film forming chamber and a heater, the film forming chamber configured to accommodate a substrate and form a film on the substrate, the heater configured to heat the substrate; a temperature controller including a temperature detector and a heater controller, the temperature detector configured to detect a temperature of at least one of inside and outside the film forming chamber, the heater controller configured to control the heater to heat the substrate at a predetermined temperature according to the temperature detected by the temperature detector; and a system controller including a film formation end time determining device configured to determine an end time of the film formation, before the temperature detected by the temperature detector is substantially constant and after the substrate is heated by the heater.

### BRIEF DESCRIPTION OF THE SEVERAL VIEWS OF THE DRAWING

FIG. 1A is a diagram showing a schematic structure of a semiconductor manufacturing system according to an embodiment of the present invention;

FIG. 1B is a structure diagram of the LP-CVD apparatus which is the semiconductor manufacturing system shown in FIG. 1A;

FIG. 2 is a flow chart showing the flow of processing in the CVD apparatus;

FIG. 3 is a flow chart showing the flow of processing in the CVD apparatus;

FIG. 4 is a flow chart showing the flow of processing in the CIM;

FIG. 5 is a flow chart showing the flow of processing of the CIM;

FIG. 6 is a flow chart showing the flow of processing of the CIM;

FIG. 7 is a flow chart showing the flow of processing in the film thickness measuring device;

FIG. 8 is a diagram showing data exchanged and wafer sent/received between devices;

FIG. 9 is a diagram showing the flow of data and wafer between the devices;

FIG. 10A is a diagram for explaining correlation coefficient; and

FIG. 10B is a diagram for explaining correlation coefficient.

### DETAILED DESCRIPTION OF THE INVENTION

Hereinafter, embodiments of the present invention will be described with reference to the accompanying drawings.

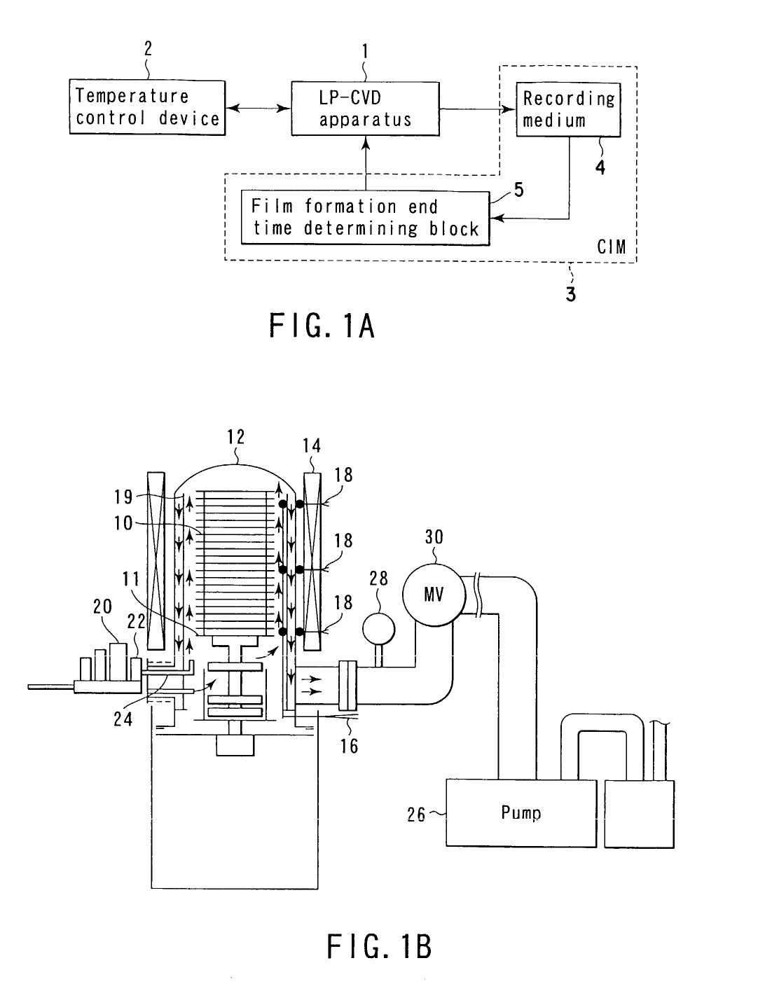

FIG. 1A is a block diagram showing the schematic structure of the semiconductor manufacturing apparatus according to an embodiment of the present invention. FIG. 1B is a specific structure diagram showing a low pressure (LP) chemical vapor deposition (CVD) apparatus (hereinafter referred to as only the CVD apparatus) of the semiconductor manufacturing apparatus shown in FIG. 1A.

The semiconductor manufacturing apparatus of this embodiment comprises largely a CVD apparatus 1, a temperature control device 2 and a system controller 3 of the type of computer integrated manufacturing (CIM) for controlling manufacturing with a computer.

The CVD apparatus 1 includes a wafer 10, a chamber 12 composed of quartz tube used for forming a film on a wafer and a heater 14 for heating the wafer.

Air is exhausted from the chamber of the CVD apparatus 1 with a pump 26 so as to produce a decompressed state and then source gas is introduced into the chamber through a nozzle 24. The quantity of gas introduced into the chamber is controlled by the mass flow controller (MFC) 20 and a valve 22. The chamber 12 contains an inner quartz tube 19 and gas introduced into the chamber passes through the inner quartz tube 19. After that, the gas is exhausted through a gap between the inner quartz tube 19 and the chamber 12, which is an outer quartz tube. In the chamber 12, a predetermined pressure is maintained by adjusting the degree of opening of its main valve MV3O based on an indication value on a pressure gauge 28.

A temperature control device 2 contains temperature sensors 16, 18 provided inside and outside the chamber and a heater control device (not shown) for controlling the heater so as to heat a wafer at a predetermined temperature based on the temperature detected by the temperature sensors 16, 18. The temperature sensor 16 provided inside the chamber is composed of an inner thermocouple and the temperature sensor 18 provided outside the chamber is composed of an outer thermocouple. If drop in temperature detection accuracy is permitted, only any one of the inner temperature sensor 16 and the outer temperature sensor 18 may be provided.

The temperature of the wafer 10 disposed within the chamber 12 is controlled by the aforementioned heater control device which controls the heater based on a temperature measured with the inner thermocouple which is the temperature sensor 16 provided inside the chamber and the outer thermocouple which is the temperature sensor 16 provided outside the chamber. Source gas introduced into the chamber 12 is decomposed by heat in the chamber 12, so that film is formed on the wafer 10 placed on a board 11 in the chamber 12.

The control system CIM 3 includes a recording medium 4 for recording information sent from the CVD apparatus 1 and a film formation end time determining circuit 5 for determining the film formation end time of the aforementioned film before a temperature detected by the heater becomes substantially constant after the wafer is heated by the heater.

The CVD apparatus 1 has film forming processing system for executing film forming processing if a temperature detected by the temperature sensor exceeds a predetermined temperature (target value).

Although FIG. 1 indicates the CVD apparatus 1 separately from the temperature control device 2, it is permissible to employ such a temperature control device provided CVD apparatus that the CVD apparatus 1 contains the temperature control device 2.

The end time determining circuit 5 is capable of reading information recorded in the recording medium 4.

Also, regarding starting the film forming operation, a configuration can be employed such that a CVD device having means for performing a film forming processing when a temperature detected by a temperature sensor exceeds a predetermined temperature (a target temperature) is used as the CVD system 1 and a film forming processing is started when the temperature detected exceeds the predetermined temperature. Alternatively, a configuration may be employed such that a CVD having film formation start time determining means for instructing the CVD apparatus 1 to start a film formation when a temperature detected by a sensor exceeds a predetermined temperature is used as the CIM 3 and a film forming processing is started by inputting a film formation start instruction signal of the film formation start time determining means to the CVD system 1 when the temperature detected exceeds the predetermined temperature. In the latter case, the end time determining block 5 may be modified to film formation start/end time determining means by incorporating the film formation start time determining means into the end time determining block 5.

Alternatively, regarding starting the film forming operation, a configuration can be employed such that a CVD apparatus having means for performing a film forming processing when a processing time exceeds a predetermined time (a target time) is used as the CVD apparatus 1 and a film forming processing is started when the processing time exceeds the predetermined time. Alternatively, a configuration can be employed such that a CIM having film formation start time determining means which instructs the CVD apparatus 1 to start a film forming when the processing time exceeds a predetermined time is used as the CIM and a film forming processing is started by inputting a film formation start instruction signal of the film formation start time determining means into the CVD apparatus 1 when the processing time exceeds the predetermined time. In the latter case, the end time determining block 5 may be modified to a film formation start/end time determining portion by incorporating the film formation start time determining means into the end time determining block 5.

The semiconductor manufacturing system having such a structure is capable of determining the film formation start time and end time before the temperature of the wafer is constant by the CIM 3. Consequently, waiting time from process start to stabilization of temperature is reduced, thereby shortening time necessary for film formation.

Hereinafter, the semiconductor manufacturing apparatus of this embodiment will be described in detail.

The temperature control device 2 has the temperature sensors 16, 18 called thermocouple or pyrometer at least either inside or outside the chamber so as to acquire their measured temperature in the form of a signal. A difference between the measured temperature value and a set temperature corresponding to the target temperature is computed with a PID (Proportional Integral Differential) controller, not shown, provided in the temperature control device 2, so that its result is used to determine a power to be supplied to the heater.

A drive signal corresponding to a determined supply power is outputted to an output device, not shown, so as to determine electricity supplied to the heater. The output device is connected to the temperature control device 2 and electricity corresponding to the drive signal outputted by the temperature control device 2 is supplied to the heater.

The PID control includes temperature rise stabilizing function which can control temperature stabilization during a temperature rising of each process to a target according to an instruction from the CIM 3.

Hereinafter, the functions possessed by the CVD apparatus 1, CIM 3 and film thickness measuring device will be described.

The CVD apparatus 1 contains transmission-to-CIM function for exchanging information with the CIM 3 in real time, CIM transmission data arrangement function for arranging data (inner/outer thermocouple, power and the like) to be sent to the CIM 3, step-up function for changing the state of the device from temperature rise step to film forming step based on data received from the CIM 3, optimum temperature transmission function for transmitting data to an optimum temperature control device 2 according to an instruction from the CIM 3, and receiving-from-CIM function for acquiring information about film formation start time, optimum PID control execution coefficient, film formation end time and the like from the CIM 3. Further, it contains automatic film formation end function for terminating the film forming processing according to an instruction of the CIM 3 when it is determined that the thickness of the film on the wafer acquired by computation of the CIM 3 is equal to a target thickness.

The CIM 3 comprises an external storage device composed of temperature change time error correcting function composed of a microcomputer and the like and RAM for storing information (temperature sensor, power, film thickness and the like) of past time, a correlation coefficient determining mechanism for computing a reference value with respect to how the temperature change during film formation is different from previous data, and a film formation end time computing function employing a film formation rate table which is used when the correlation coefficient is large and created from previous temperature change data. The external storage device and the recording medium 4 may be the same one or different ones.

The CIM3 comprises current film thickness determining function which is a film thickness determining method used when the correlation coefficient is small and for computing a current film thickness, automatic film formation end mechanism for transmitting an instruction about film formation end to the CVD apparatus 1 when a predetermined film thickness is reached, film formation period start determining function for determining the period in which the film formation is started, and reference film thickness/activation energy measuring mechanism for computing the reference film thickness and activation energy based on previous temperature measuring data, film thickness measuring data, power consumption and internal specific heat in the chamber.

The CIM 3 further comprises creation function for film forming rate table used for the reference data usage method which is employed when the correlation coefficient is large, transmission function for transmitting information to external devices such as CVD apparatus 1, display device or the like, and receiving function for the CIM to receive data. The display device is used for transmitting a difference between the temperature of a current process and data (reference data) relating to the temperature determined by the environment of the CVD apparatus 1 to an operator.

The film thickness measuring device comprises film thickness measuring function and CIM transmission function for transmitting a measured film thickness to the CIM 3.

Exchange of information (data) among respective devices (CVD apparatus 1, CIM 3, film thickness measuring device) is carried out through network.

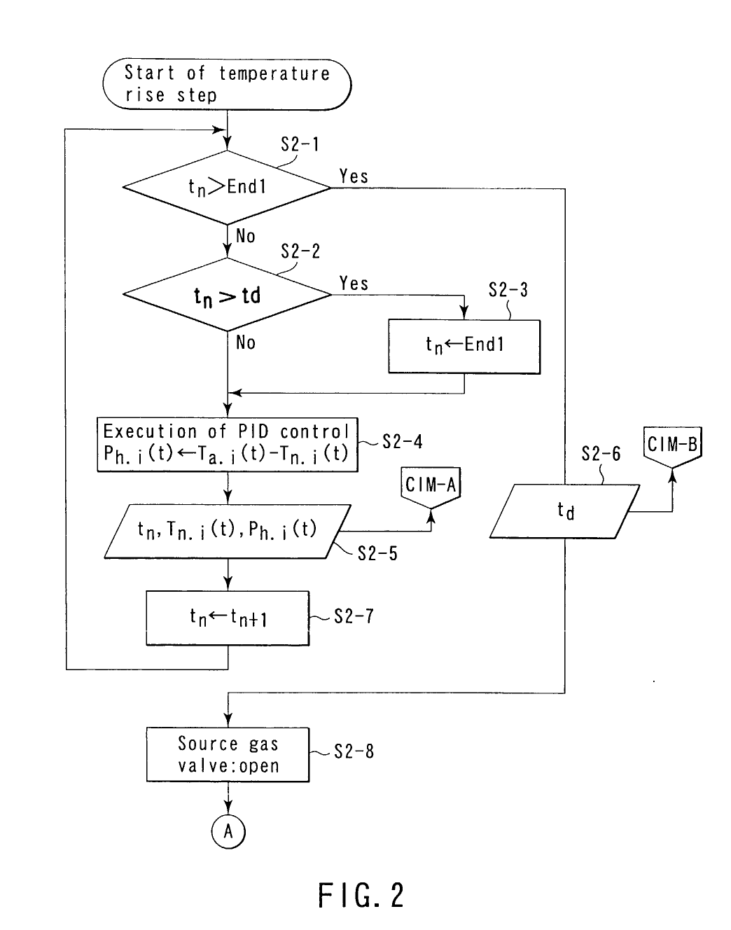

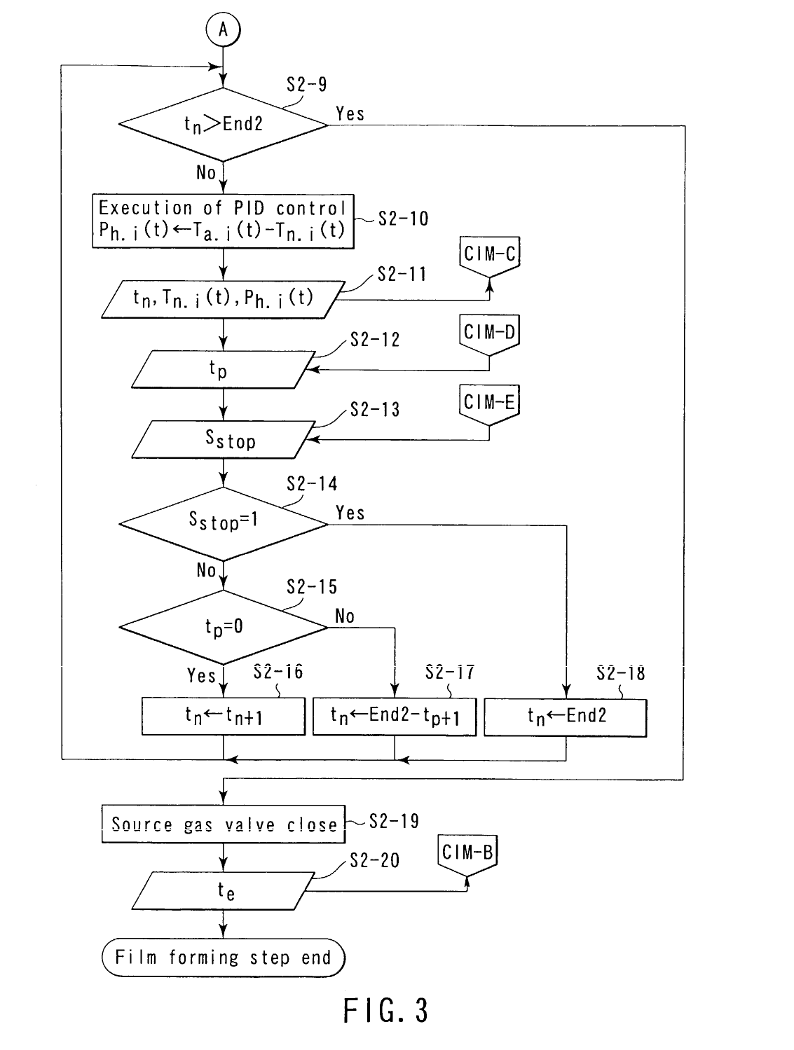

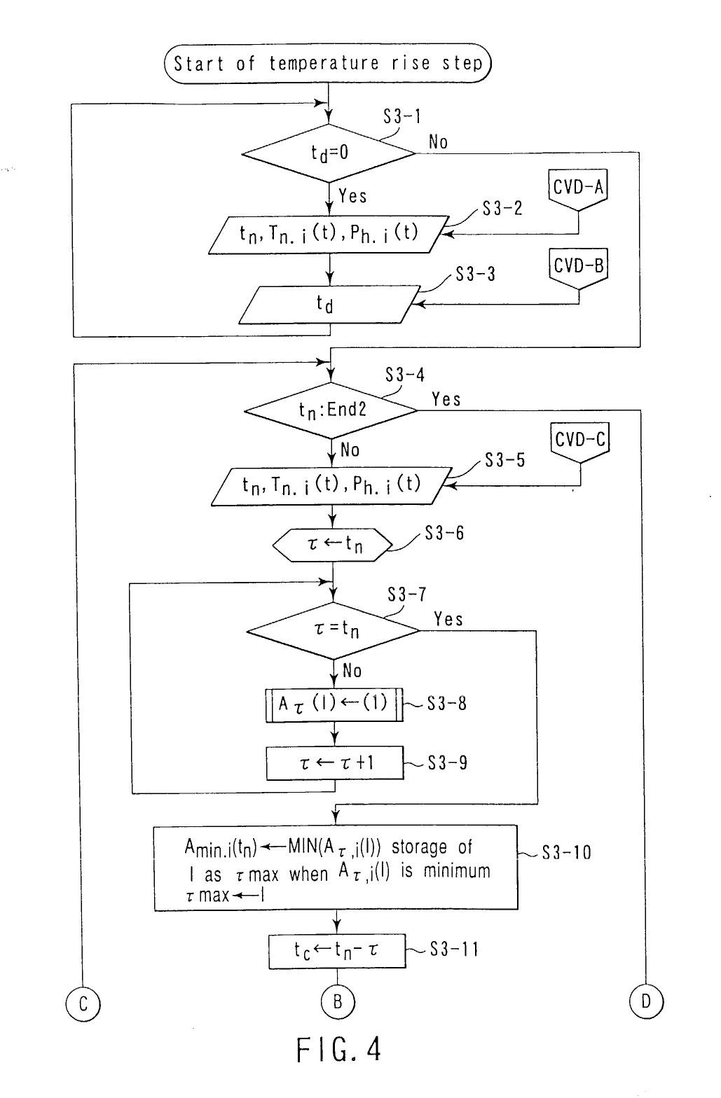

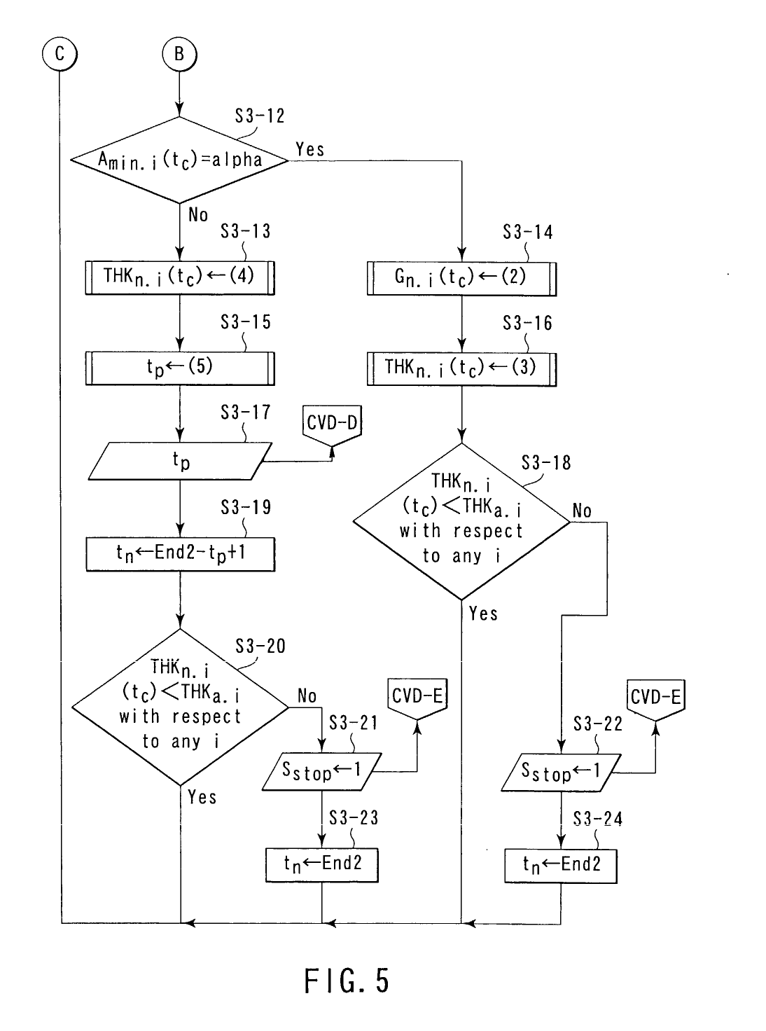

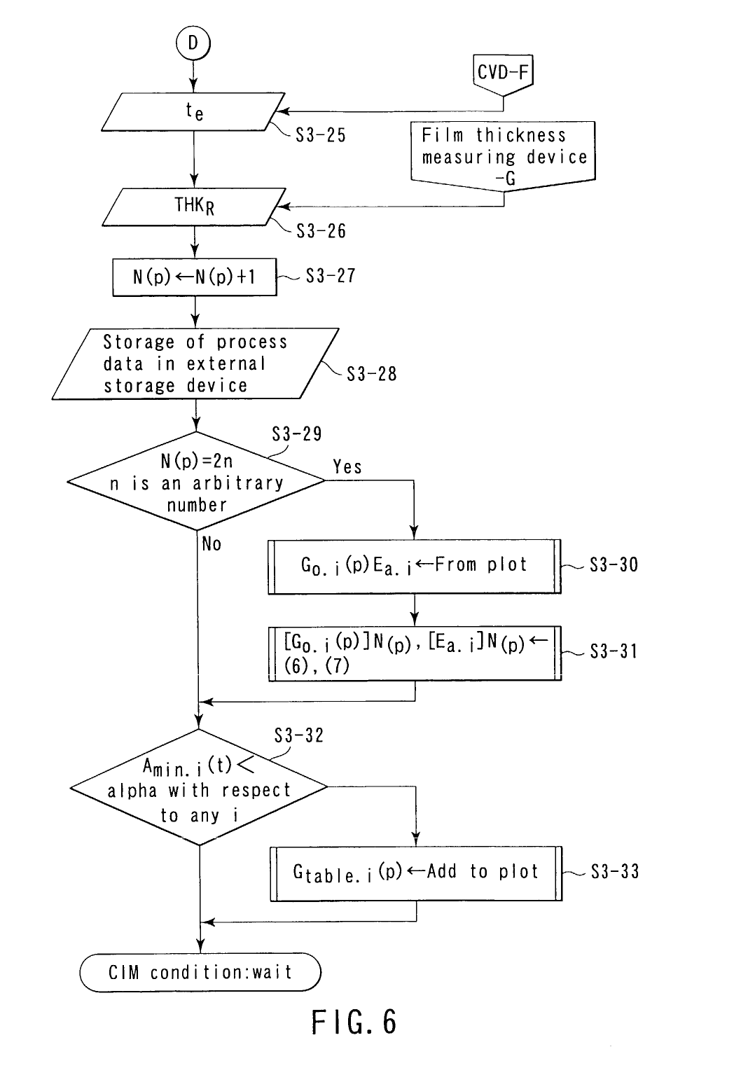

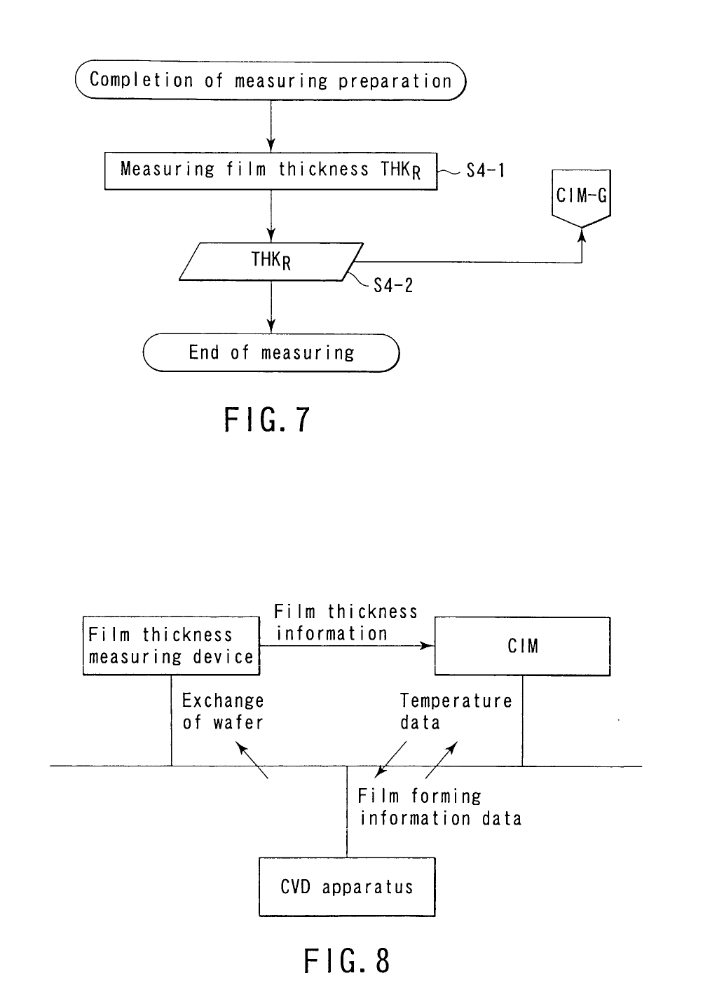

The flow of processing and the respective functions will be described in detail with reference to FIGS. 2-7. FIGS. 2 and 3 are flow charts showing the flow of processing in the CVD apparatus 1. FIGS. 4, 5 and 6 are flow charts showing the flow of processing in the CIM 3. FIG. 7 is a flow chart showing the flow of processing in the film thickness measuring device.

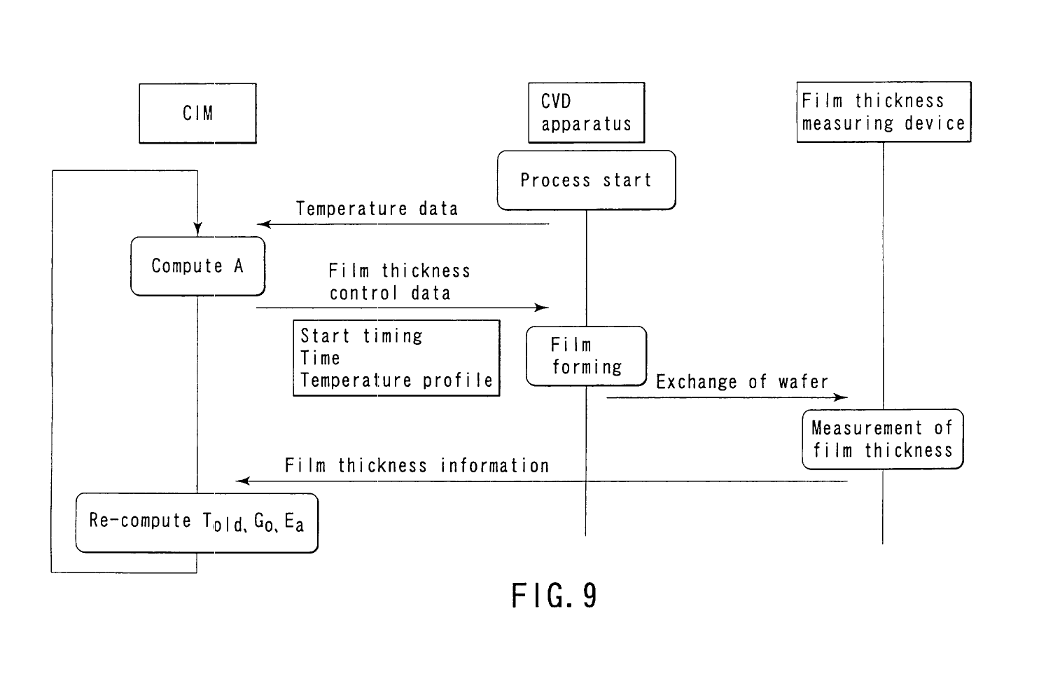

As regards these flow charts, in a diamond shaped box step indicating an input, for example, steps S3-2, S3-3, S3-5 in FIG. 4, CVD-A, CVD-B, CVD-C indicate the same CVD apparatus and the direction of an arrow from the CVD-A or the like indicates that data is inputted from the CVD apparatus into the CIM. That is, they indicate the same devices although the suffixes such as -A, -B are different and the direction of an arrow indicates the direction of data flow between devices. FIG. 8 is a diagram showing data and a wafer exchanged between the devices and FIG. 9 is a diagram showing the flow of data and wafer between the devices.

The variables used in the above described flow charts will be described in Table 1.

TABLE 1

| | |
|---|---|
| Aᵢ (t) | Correlation coefficient |
| A_{min, i} (t) | The smallest correlation coefficient |
| A_{τ, i} (t) | Correlation coefficient when there |
| | is a time error component |
| E_{a,i} | Reference activation energy [eV] |
| End1 | Temperature rise end step (film |
| | formation start step) |
| End2 | Film formation end step |
| Go_{o, i} (P) | Reference rate of film formation |
| | under a pressure (nm/min) |
| G_{n, i} (t) | Film formation rate at a time |
| | [nm/step] |
| G_{table, i} (t) | Film formation rate table |
| I | Variable used in program |
| i | Device number (of a temperature |
| | sensor or the like) a unique number |
| | at a measuring position |
| N (p) | The number of film formations of the |
| | same system under Each film forming |
| | gas partial pressure |
| P_{h,i} (t) | Change in output of heater with time |
| | [W/step] |
| Sₛₜₒₚ | End signal |
| t_{c} | Time component after correction with |
| | time error component [step] |
| t_{d} | Film formation start time [step] |
| tₑ | Film formation end time |
| tₙ | Current time [step] |
| tₚ | Estimated film formation end time |
| | [step] |
| T_{a, i} (t) | Time-basis target temperature data |
| | [° C.] |
| Td | Film formation start temperature |
| | [° C.] |
| T_{n, i} (t) | Time-basis temperature data in |
| | current step detected by a first |
| | temperature sensor [° C.] |
| T_{o, i} (t) | Reference temperature time-basis |
| | data |
| THK_{a, I} | Target film thickness [nm] |
| THK_{n, I} (t) | Current film thickness [nm] |
| THK_{R} | Measured film thickness [nm] |
| τ | Time Error component [step] |
| τₘₐₓ | Time error component in which the |
| | correlation coefficient is minimized |
| | [step] |
| alpha | A value used for determining a film |
| | thickness determining method for use |

In the CVD apparatus 1, initial values are set such that tₙ=0, T_{n,i}(t)=0, P_{h.i}(t)=0, T_{a,i}(t)=0, t_{d}=0, tₚ=0, Sₛₜₒₚ=0, tₑ=0, End1=100000[step], and End2=100000[step]. Also, T_{d} and T_{a,i}(t) are set to temperatures suitable for formation of polysilicone film as initial values. In the CIM 3, initial values are set such that t_{d}=0, tₙ=0, T_{n,i}(t)=0, P_{h.i}(t)=0, τ=0, I=0, A_{τ,i}(I)=0, τₘₐₓ=0, A_{min,i}(t)=0, G_{n,i}(t)=0, t_{c}=0, THK_{n,i}(t)=0, tₚ=0, Sₛₜₒₚ=0, THK_{R}=0, tₑ=0, End2=100000[step], and alpha =1. Also, THK_{a,i} is set to a thickness of the film [nm] to be formed. In the film thickness measuring device, THK_{R}=0 is used as an initial value. As the above-mentioned values, optimum values are determined according to previous experimental data.

When the CVD apparatus 1 needs to execute heat treatment, a difference occurs between an target temperature and a temperature measured by the temperature sensor provided in the CVD apparatus 1. A signal is sent from the temperature control device 2 so as to raise the output of the heat to eliminate that difference (step S2-4). At the same time, by using transmission/receiving to CIM function, the temperature control device 2 transmits data about changes in temperature with time Tn, i(t), measured with the inner/outer temperature sensors and data about changes in heater output P_{h,i}(t) to the CIM 3 (step S2-5). At that moment, the PID control corrects a signal to be sent to the heater so as to achieve an ideal state in which the temperature changes primarily to time.

The CIM3 compares data about changes in temperature with time T_{n,i}(t) measured with the temperature sensor, transmitted from the temperature control device 2 with the reference temperature time-basis data T_{o,i}(t) stored in the external storage device and further data about changes in the output of the heater P_{h,i}(t) with the reference output time-basis data of heater, and executes temperature change time-basis error correcting function having the function for extracting its time-basis error component τ so as to correct the time basis error of a measured data (steps S3-1 to S3-10).

The temperature change time-basis error correcting function acquires time-basis error of data sent from the temperature control device 2 to the CIM 3 in order to acquire a minimum value of correlation coefficient computed by correlation coefficient determining function. The correlation coefficient determining function determines Aᵢ(t) according to a following equation (1) (step S3-8). The correlation coefficient Aᵢ(t) can be obtained repeatedly by the number of the temperature sensors.

$${A}_{i} ( t ) = \frac{1}{{t}_{n}} {\int }_{o}^{{t}_{n}} \vert {T}_{o , i} ( t ) - {T}_{n , i} ( t - τ ) \vert ⅆ t \qquad ( 1 )$$

tₙ: time from start of temperature rise to present time

τ: time correction component

Aᵢ(t): correlation coefficient

T_{o,i}(t): reference temperature time-basis data

T_{n,i}(t): measured temperature time-basis data

i: position of temperature sensor

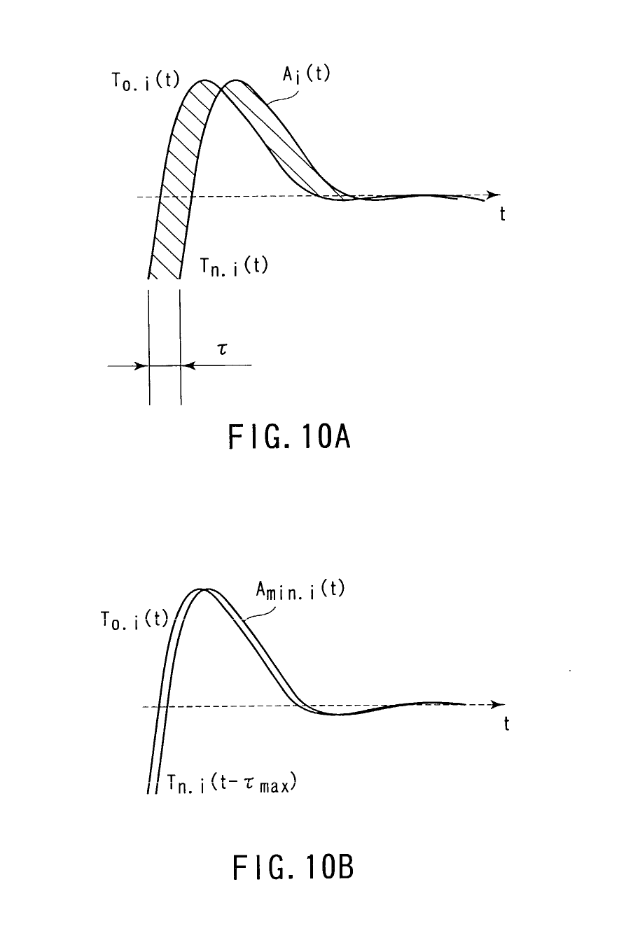

Time correction component τ in which correlation coefficient Aᵢ(t) turns to minimum value A_{min,i}(t) is assumed to be time error τₘₐₓ (step S3-10). After that, data sent from the temperature control device 2 to the CIM 3 is handled as data whose time component is corrected by τₘₐₓ (step S3-11). FIG. 10A is a diagram for explaining correlation coefficient, and FIG. 10B is a diagram for explaining correlation coefficient.

Next, a film thickness determining method is determined by the film thickness method determining function. In case of A_{min,i}(t)>alpha, because the measured temperature time-basis data T_{n,i}(t) is largely different from the previous reference temperature time-basis data T_{o,i}(t), a film thickness determining method based on a film thickness computation method for determining a film thickness without use of the previous reference temperature time-basis data T_{o,i}(t) is employed. In case of A_{min,i}(t)<alpha, a film thickness determining method based on a reference data usage method for determining a film thickness with the previous reference temperature time-basis data T_{o,i}(t) is employed (step S3-12 to S3-24). According to this embodiment, alpha is set to 1.

The film thickness computation method is achieved by the current film thickness determining function. The detail of the film thickness computation method is expressed with following equations (2) and (3) (steps 3-14, S3-16, S3-18, S3-22, S3-24).

$$\begin{matrix}{G}_{n , i} ( t ) = {G}_{o , i} ( p ) exp ( - \frac{{E}_{a , i}}{{kT}_{n , i} ( t )} ) & ( 2 ) \\ {THK}_{n , i} ( t ) = {\int }_{{t}_{d}}^{{t}_{n} - {t}_{d}} {G}_{n , i} ( t ) ⅆ t & ( 3 )\end{matrix}$$

THK_{n,i}(t): current film thickness

G_{n,i}(t): film formation rate

E_{a,i}: reference activation energy computed based on previous data

G_{0,i}(p): reference film formation rate changing depending on film forming gas partial pressure computed based on the previous data

k: Boltzmann's constant

t_{d}: film formation start time

If T_{n,i}(t) measured by the temperature control device 2 is assigned to an equation (2) (Arrhenius' equation), G_{n,i}(t) is acquired, and if the acquired G_{n,i}(t) is assigned to the equation (3), current film thickness THK_{n,i}(t) is obtained (step S3-16).

A current film thickness THK_{n,i}(t) is computed according to the film thickness computation method and if that film thickness exceeds an target thickness THK_{a,i}(t), an instruction about film formation end is transmitted to the CVD apparatus 1 by the film formation end instruction function (step S3-10, S3-22). In the CVD apparatus 1, its step-up function is activated according to the same instruction so that the state is changed from the film forming step to a next step (step S3-24).

The reference data usage method is expressed with following equation (4) (steps S3-13, S3-15, S3-17, S3-19, S3-20, S3-21, S3-23).

$${THK}_{n , i} ( t ) = {\int }_{{t}_{d}}^{{t}_{n} - {t}_{d}} {G}_{table , i} ( t ) ⅆ t \qquad ( 4 )$$

G_{table,i}(t): table of film formation rate determined depending on temperature, the number of wafers in a chamber, and film forming gas partial pressure. At the same, film formation end time is computed according to following equation (5).

$${THK}_{a , i} ( t ) = {\int }_{{t}_{d}}^{{t}_{p}} {G}_{table , i} ( t ) ⅆ t \qquad ( 5 )$$

THK_{a,i}(t): target thickness of the film

tₚ: estimated film formation end time

The reference data usage method is capable of transmitting the estimated film formation end time tₚ obtained with the equation (5) to the CVD apparatus 1 in advance.

The automatic film formation end function of the CVD apparatus 1 automatically terminates film forming step even if no instruction about film formation end is transmitted from the CIM 3 when the current time tₙ reaches the estimated film formation end time tₚ.

Thus, as compared to the film thickness computation method which determines a current film thickness THK_{n,i}(t) according to the equation (3) and terminates film forming when the current film thickness THK_{n,i}(t) exceeds a target thickness THK_{a,i}, the film forming processing can be terminated without a time necessary for computing the current film thickness of a wafer, a delay time of transmission to the CVD apparatus 1 and a delay time generated when a gas supply valve provided on the unit is closed. The error in thickness of the film thus formed is smaller by a corresponding amount.

Even if the temperature time-basis data T_{n,i}(t) in the equation (2) is replaced with the heater time-basis output data P_{h,i}(t), the semiconductor manufacturing system can be controlled without any problem in terms of the structure.

The CVD apparatus 1 and the CIM 3 can terminate the film forming step with two kinds of methods determined depending on the value of the correlation coefficient Aᵢ(t).

After a wafer is subjected to the film forming processing, the film thickness measuring device measures an actual film thickness THK_{R} (step S4-1). The film thickness measuring device transmits film thickness data THK_{R} to the CIM 3 according to the transmission to CIM function (step S4-2).

The CIM 3 stores film thickness data THK_{R} sent from the film thickness measuring device and time-basis temperature data T_{n,i}(t) and time-basis heater output change data P_{h,i}(t) sent from the CVD apparatus 1, with time data T_{d}, tₑ and CVD apparatus state initial data such as initial temperature, number of wafers in the chamber, film forming gas partial pressure, film forming gas type and correlation coefficient Aₘᵢₙ, τₘₐₓ computed by the CIM 3 as process data, in the external storage unit. At the same time, the number of film formings N(p) of the same system under each film forming gas partial pressure possessed by the CIM 3 plus 1 is stored in the external storage device 5 and each time when the number of film formings N(p) of the same system under each film forming gas partial pressure turns to a multiple of 2, the reference film thickness, activation energy computing function is activated (steps S3-29, S3-30, S3-31).

The parameters used in steps S3-30, S3-31 are variable groups for computing the film thickness based on film thickness information acquired with the film thickness measuring device and information sent from the CVD apparatus 1.

The reference film thickness, reference activation energy computing function computes the reference film formation rate G_{o,i} (p) and the activation energy E_{a,i} using two groups of the process data based on the fact that an inverse number of a temperature is proportional to the logarithm of the film formation rate, under the same gas partial pressure condition. Then, a difference between that computed data and the reference data possessed by the CIM 3 is divided by the number of film formings N(p) of the same system under each film forming gas partial pressure and then, its result is reflected on the reference data. The reflection of the reference data is carried out according to following equations.

$$\begin{matrix}{[ {G}_{o , i} ( p ) ]}_{N ( p )} = {\frac{N ( p ) - 1}{N ( p )} [ {G}_{o , i} ( p ) ]}_{N ( p ) - 1} + \frac{1}{N ( p )} {G}_{o , i} ( t ) & ( 6 ) \\ {[ {E}_{a , i} ]}_{N ( p )} = {\frac{N ( p ) - 1}{N ( p )} [ {E}_{a , i} ( p ) ]}_{N ( p ) - 1} + \frac{1}{N ( p )} {E}_{a , i} ( t ) & ( 7 )\end{matrix}$$

N(p): the number of film formings of the same system under each film forming gas partial pressure

If A_{min,i}<alpha occurs when film formation ends, a value corresponding to film forming process data is added to the table of G_{table,i}(t).

As soon as the above processing ends, the CIM 3 gets into waiting condition so as to prepare for next film forming processing.

The present invention is not restricted to the above-described embodiments. Although a case where the quantity of the CVD apparatuses is singular has been described in the above embodiments, the semiconductor manufacturing system of the present invention can be carried out in case where the quantity of the CVD apparatuses is plural. Further, the present invention is applicable to other types of the CVD apparatus as well as the LP-CVD apparatus. Further, the present invention is also applicable to film forming apparatus other than the CVD apparatus.

As described above, the present invention is capable of achieving the semiconductor manufacturing system which enables process time necessary for film forming to be reduced.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device manufacturing system comprising:
a film forming device including a film forming chamber and a heater, the film forming chamber configured to accommodate a substrate and form a film on the substrate, the heater configured to heat the substrate;
a temperature controller including a temperature detector and a heater controller, the temperature detector configured to detect a temperature of at least one of inside and outside the film forming chamber, the heater controller configured to control the heater to heat the substrate at a predetermined temperature according to the temperature detected by the temperature detector; and
a system controller including a film formation end time determining device configured to determine an end time of the film formation, before the temperature detected by the temperature detector is substantially constant and after the substrate is heated by the heater.

2. A semiconductor device manufacturing system according to claim 1, in which the system controller is of computer integrated manufacturing.

3. A semiconductor device manufacturing system according to claim 2, in which the system controller comprises a film thickness calculating device configured to calculate a thickness of the film formed on the substrate according to information from the film forming device.

4. A semiconductor device manufacturing system according to claim 3, further comprising a film thickness measuring device configured to measure a thickness of the film formed on the substrate, and in which the system controller comprises a variable correcting device configured to correct variables used to calculate the thickness of the film according to information of the film thickness measured by the film thickness measuring device and said information from the film forming device.

5. A semiconductor device manufacturing system according to claim 2, in which the system controller comprises a time transforming device configured to transform a time when the time transforming device receives information of the temperature detected by the temperature detector to a time when the temperature has been detected by the temperature detector.

6. A semiconductor device manufacturing system according to claim 2, in which the system controller comprises a time transforming device configured to transform a time when the time transforming device receives information of the temperature detected by the temperature detector to a time when the temperature has been detected by the temperature detector.

7. A semiconductor device manufacturing system according to claim 2, in which the system controller comprises a time transforming device configured to transform a time when the time transforming device receives information of the temperature detected by the temperature detector to a time when the temperature has been detected by the temperature detector.

8. A semiconductor device manufacturing system according to claim 5, in which the time transforming device comprises a correlated coefficient determining device configured to determine a correlated coefficient of the temperature according to a time-basis temperature variation data, the time-basis temperature variation data being obtained in the system controller and formed of the information of the temperature detected by the temperature detector and the time when the time transforming device receives the information of the temperature detected by the temperature detector.

9. A semiconductor device manufacturing system according to claim 6, in which the correlated coefficient determining device uses a difference between a previous time-basis temperature variation data as a reference and a time-basis temperature variation data of the temperature being detected to determine said correlated coefficient.

10. A semiconductor device manufacturing system according to claim 3, in which the film thickness calculating device uses said correlated coefficient.

11. A semiconductor device manufacturing system according to claim 2, in which the system controller comprises a film thickness calculating device configured to calculate a thickness of the film being formed.

12. A semiconductor device manufacturing system according to claim 2, in which the system controller comprises an anticipated end time calculating device configured to calculate an anticipated end time of formation of the film being formed.

13. A semiconductor device manufacturing system according to claim 11, in which the film thickness calculating device calculates the thickness of the film being formed, according to a table corresponding to a change of a formation rate of the film being formed with time.

14. A semiconductor device manufacturing system according to claim 12, in which the anticipated end time calculating device calculates the anticipated end time of formation of the film being formed, according to a table corresponding to a change of a formation rate of the film being formed with time.

15. A semiconductor device manufacturing system according to claim 11, in which the system controller comprises a film-formation end indicating signal providing device configured to provide a signal indicating an end of the film-formation to the film forming device when the thickness of the film being formed is calculated by the thickness calculating device and reaches a target thickness of the film.

16. A semiconductor device manufacturing system according to claim 13, in which the system controller comprises a film-formation end indicating signal providing device configured to provide a signal indicating an end of the film-formation to the film forming device when the thickness of the film being formed is calculated by the thickness calculating device and reaches a target thickness of the film.

17. A semiconductor device manufacturing system according to claim 15, in which the film forming device comprises a film-formation performing device configured to perform a formation of the film when the temperature detected by the temperature detector exceeds a predetermined temperature.

18. A semiconductor device manufacturing system according to claim 16, in which the film forming device comprises a film-formation performing device configured to perform a formation of the film when the temperature detected by the temperature detector exceeds a predetermined temperature.

19. A semiconductor device manufacturing system according to claim 15, in which the system controller comprises a film-formation starting indicating signal providing device configured to provide a signal indicating a start of the film-formation to the film forming device when the temperature detected by the temperature detector exceeds a predetermined temperature.

20. A semiconductor device manufacturing system according to claim 16, in which the system controller comprises a film-formation starting indicating signal providing device configured to provide a signal indicating a start of the film-formation to the film forming device when the temperature detected by the temperature detector exceeds a predetermined temperature.
